(19) United States
(12) Patent Application Publication
(10) Pub. No.: US 2022/0208528 A1
(43) Pub. Date: Jun. 30, 2022

(54) DEVICE FOR ADJUSTING PLASMA EDGE IN PROCESSING CHAMBER AND CONTROL METHOD THEREOF

(71) Applicant: PIOTECH INC., Shenyang (CN)

(72) Inventors: Saiqian Zhang, Shenyang (CN); Jian Li, Shenyang (CN)

(21) Appl. No.: 17/550,114

(22) Filed: Dec. 14, 2021

(30) Foreign Application Priority Data
Dec. 31, 2020 (CN) 202011627023.7

(51) Int. Cl. H01J 37/32

(52) U.S. Cl. CPC H01J 37/32642; H01J 2237/332; H01J 37/32724

(57) ABSTRACT

The present invention relates to a device for adjusting a plasma curve. The device includes a metal adjusting ring having an inner side surface, an inclined surface and a top surface. The inclined surface extends downwards from the top surface to the inner side surface. The inclined surface and the top surface define an included angle, which is within a range of 150 degrees to 120 degrees.

### CROSS-REFERENCE TO RELATED APPLICATIONS

This non-provisional application claims priority under 35 U.S.C. § 119(a) to Patent Application No(s). 202011627023.7 filed in China on Dec. 31, 2020, the entire contents of which are hereby incorporated by reference.

### BACKGROUND OF THE INVENTION

### Field of the Invention

The present invention relates to a plasma processing device in semiconductor manufacturing and, more particularly, to a device for adjusting a plasma field distribution in a processing chamber and a control method thereof.

### Description of the Prior Art

Plasma processing is used for depositing a substance on a substrate to form a thin film, such as using a known plasma enhanced chemical vapor deposition (PECVD) method to form a dielectric film on a substrate. In plasma processing, plasma distribution, uniformity and density affecting the formation of a thin film are critical, and this is because these factors lead to a difference between a film thickness at the center of a substrate and a film thickness at the edge of a substrate. Appropriate plasma distribution, uniformity and density can result in a thin film with a uniform thickness. The ideal outcome above relies on adjustment and control of a plasma distribution curve during processing.

Therefore, there is a need for developing a device that effectively adjusts, modulates or controls a plasma field distribution in a processing chamber during a processing period and a control method thereof, which are also advantageous in terms of cost.

### SUMMARY OF THE INVENTION

It is an object of the present invention to provide a device for adjusting a plasma curve. The device includes a metal adjusting ring, which has an inner side surface, an inclined surface and a top surface. The inclined surface extends downwards from the top surface to the inner side surface, and the inclined surface and the top surface define an included angle, wherein the included angle is within a range of 150 degrees to 120 degrees.

It is another object of the present invention to provide a device for adjusting a plasma curve. The device includes: a support plate, having a carrier region and a peripheral region around the carrier region; and a metal adjusting ring, embedded and extended in the peripheral region of the support plate, the metal adjusting ring having an inner side surface facing the carrier region, an inclined surface and a top surface. The inclined surface extends downwards from the top surface to the inner side surface, and the inclined surface and the top surface define an included angle, wherein the included angle is within a range of 150 degrees to 120 degrees.

In a specific embodiment, the peripheral region of the support plate is provided with a ceramic ring, and the ceramic ring envelops the metal adjusting ring in the peripheral region of the support plate.

In a specific embodiment, at least a portion of the peripheral region of the support plate is higher than the carrier region. In a specific embodiment, the support plate has a connector element. The connector element provides an electrical connection between a conducting wire and the metal adjusting ring, for the metal adjusting ring to receive a direct-current (DC) voltage through the conducting wire.

In a specific embodiment, the connector element includes: a wiring sleeve, at least partially embedded in the support plate and enveloping the conducting wire; a fixing cap, securing the wiring sleeve in the support plate; and a protection cover, at least partially extending to an exterior of the support plate and enveloping at least a portion of the wiring sleeve.

It is yet another object of the present invention to provide a method for controlling the device. The method includes: lifting the support plate in a processing cavity by a motor; lifting the conducting wire by a motion element to lift the conducting wire and the support plate synchronously. The motion element is mechanically connected to the motor, such that the motor and the motion element are moved synchronously.

In a specific embodiment, the motion assembly includes: an adaptor, connected to a terminal of the conducting wire; a sealing portion, connected to the adaptor and sealing the terminal of the conducting wire; a corrugated tube, connected to the sealing portion and enveloping the adaptor; and a motion support, connected to the sealing portion and coupled to a motor controlling the support plate.

### BRIEF DESCRIPTION OF THE DRAWINGS

The above and other characteristics and advantages of the present invention become more apparent by referring to the embodiments described with the accompanying drawings below.

FIG. 1 shows a block schematic diagram of a semiconductor processing device;

FIG. 2 depicts a plasma adjusting device according to a first embodiment of the present invention;

FIG. 3 is a cross-sectional schematic diagram of the device of the first embodiment;

FIG. 4A and FIG. 4B depict a plasma adjusting device according to a second embodiment of the present invention;

FIG. 5 is a cross-sectional diagram of a processing chamber according to the second embodiment of the present invention; and

FIG. 6 depicts a motion element (connecting element) included in the second embodiment of the present invention.

### DETAILED DESCRIPTION OF THE EMBODIMENTS

In the detailed description of the various exemplary embodiments below, reference is made to the accompanying drawings that form a part of the present invention. It is to be understood that the embodiments are given by way of examples, and the implementation of these specific embodiments can be carried out on the basis of the description of the examples. Thus, sufficient details are given for a person skilled in the art to perform the specific embodiments. Moreover, it is to be understood that, other specific embodiments can be used and other modifications can be made without departing form the spirit or scope of the specific embodiments. In addition, the reference to “a specific embodiment” does not need to belong to the same or such single specific embodiment. Thus, the detailed description below is not to be construed as limitations, and the scope of the specific embodiments described shall be defined by the appended claims only.

Throughout the present application and the claims, unless otherwise explicitly specified in the context, the terms used below contain meanings associated with the explanations given below. When in use, unless otherwise explicitly specified, the term “or” refers to the “or” which means “including . . . ”, and the term is equivalent to “and/or”. Unless otherwise explicitly specified in the context, the term “according to” is non-exclusive, and allows being in accordance with numerous other factors not described herein. Moreover, throughout the present application, meanings of “a/an”, “one” and “the” include references of plural forms. The meaning of “in . . . ” includes “inside . . . ” and “on . . . ”.

The description below provides a brief summary of the innovative subject matter to provide fundamental understanding for certain implementations. The summary given is not expected to serve as a comprehensive overview. Moreover, the summary is not expected to serve for identifying main or critical elements, or for describing or limiting the range. The object of the summary is to present certain concepts in a brief form, and to act as a preamble of the more detailed description that follows.

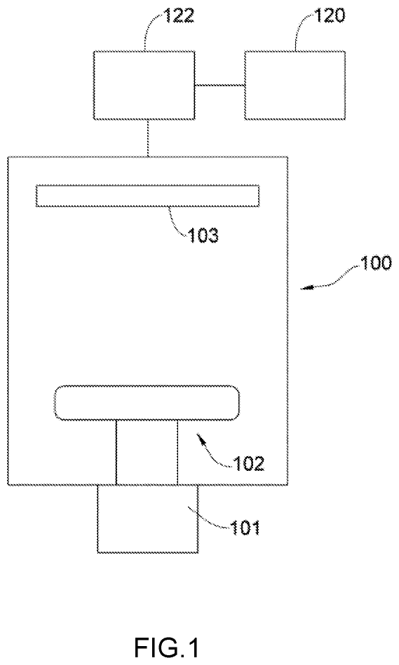

FIG. 1 shows a processing apparatus for semiconductor manufacturing, and particularly a processing apparatus for carrying out plasma process. The processing apparatus includes a processing chamber 100, which has a cavity for accommodating various processing devices and components. The processing chamber 100 is connected to an exhaust system (not shown), wherein the exhaust system is configured to control a pressure in the cavity. The top of the processing chamber 100 is connected to a gas supply system (not shown), which is configured to provide a reaction gas to the chamber. The bottom of the processing chamber 100 is connected to a motor 101 and a support component 102, wherein the motor 101 controls lifting of the support component 102 in the chamber.

A typical processing apparatus used for plasma processing includes a radio-frequency (RF) signal generator 120 and a matcher 122. An output terminal of the RF signal generator 120 is electrically coupled to an input terminal of the matcher 122. An output terminal of the matcher 122 is electrically coupled to an electrode 103 in a housing 100. As shown, the processing chamber 100 is provided therein with an electrode 103 close to the top, and the electrode is generally a part of a showerhead element. The matcher 122 is electrically coupled to the electrode 103. The arrangement of the RF signal generator and the matcher are not limited to the example given in the disclosure.

The RF signal generator 120 is configured to generate one or more RF signals. In one embodiment, the RF signal generator 120 may include one or more RF signal generating units, wherein an operating frequency of each of the multiple RF signal generating units may be different from that of another. In the prior art, the RF signal generator 120 may be implemented by at least one low-frequency RF signal generating unit and at least one high-frequency RF signal generating unit.

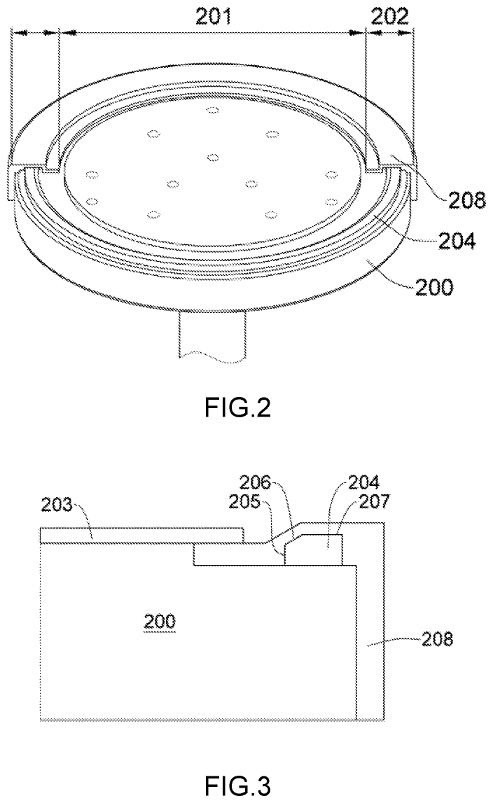

FIG. 2 shows an appearance of the top of a support component, such as the support component 102 in FIG. 1. FIG. 3 shows a cross-sectional schematic diagram of a first embodiment. The configurations or components shown in FIG. 2 and FIG. 3 show a device for adjusting a plasma curve according to the first embodiment of the present invention. The device includes a support plate 200 for supporting a substrate or a wafer. The support plate 200 has a carrier region 201 and a peripheral region 202. The carrier region 201 is a main region for carrying the substrate, and may include multiple substrate lifting or contact elements, such as lift pins. The peripheral region 202 is located on the periphery of the support plate 200 and surrounds the carrier region 201. The peripheral region 202 may be configured to serve purposes of limiting the position of a substrate carried or other purposes. For example, at least a portion of the peripheral region 202 may be slightly higher than the carrier region 201 so as to limit a horizontal movement of a substrate 203, as shown in FIG. 2.

The support plate 200 is provided with a metal adjusting ring 204, which is on the same side as the substrate carried and is configured to extend in the peripheral region 202. Basically, the metal adjusting ring 204 is located at a position on an outer side of the substrate carried and may be slightly higher or slightly lower than the substrate. As shown in FIG. 2, the metal adjusting ring 204 is located, in the peripheral region 202, at a recessed position lower compared to the carrier region 201. The metal adjusting ring 204 has an inner side surface 205 facing the carrier region 201, an inclined surface 206 and a top surface 207. The inclined surface 206 extends downwards from the top surface 207 to the inner side surface 205, and the inclined surface 206 and the top surface 207 define an included angle that is within a range of 150 degrees to 120 degrees. During plasma processing, although no voltage is applied, the metal adjusting ring 204 is capable of modulating an edge curve of plasma, and more particularly, a plasma field distribution around the substrate. Compared to a conventional configuration without the metal adjusting ring 204, a horizontal field distribution in the cavity with the metal adjusting ring 204 is more ideal, and is conducive to forming a thin film having a uniform thickness from the center to the periphery of the substrate. Metal adjusting rings of different geometric shapes (e.g. the cross section shape shown in FIG. 2) provide different modulation effects. However, it is discovered that a metal ring configured with the inclined surface provides the most significant modulation effect on the plasma field distribution.

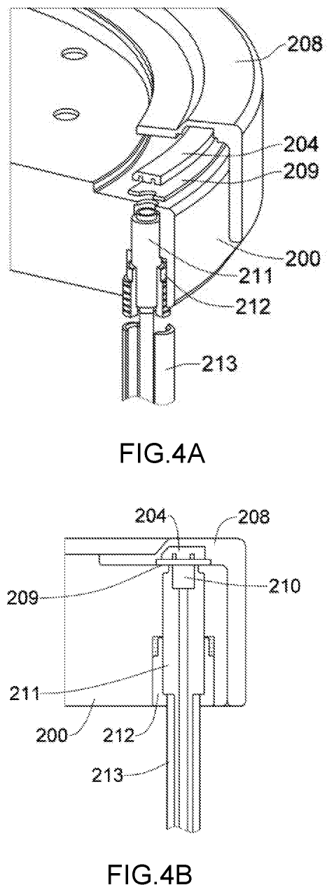

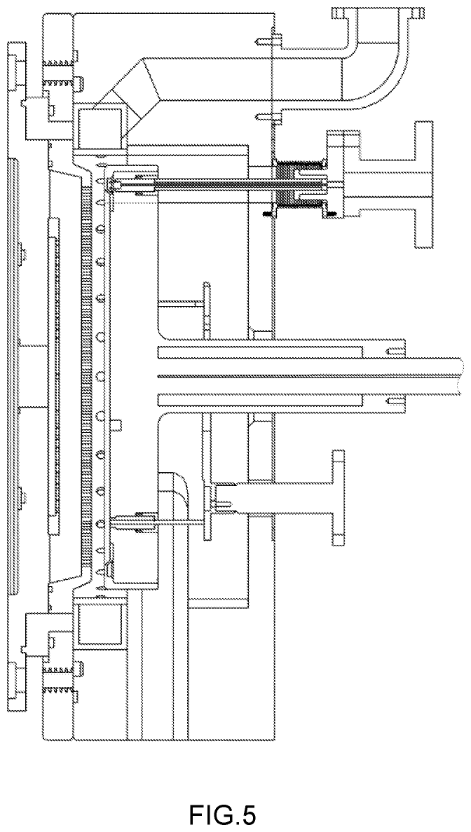

The support plate 200 includes a ceramic ring 208 configured in the peripheral region 202 and enveloping the metal adjusting ring 204, so as to embed and seal the metal adjusting ring 204 in the support plate 200. FIG. 4A shows a state where the ceramic ring 204 and the support plate 200 are separated. It is seen that the ceramic ring 208 has a covering portion (not denoted) and an enveloping portion (not denoted) extending downwards from the covering portion. An inner side surface of the covering portion is configured with a groove corresponding to the shape of the metal adjusting ring 204. The enveloping portion extends downwards so as to envelop a side surface of the support plate 200, as shown in FIG. 2. The top of the ceramic ring 208 may be configured as a step structure or a sloped structure to serve as a limitation against a horizontal movement of the substrate. Moreover, a sealing means may be used to prevent gas from eroding the metal adjusting ring 204 between the ceramic ring 208 and the support plate 200.

Although not indicated, the support plate 200 is embedded with components such as an electrode, a heating coil, a thermal insulator, an electrostatic adsorption panel and/or conductor channel, and these components are not further described herein.

FIG. 4A and FIG. 4B show a second embodiment of the present invention, which differs from the first embodiment in that a voltage connection means is introduced. Basically, the metal adjusting ring 204 and the ceramic ring 208 of the support plate 200 are configured in a way the same as that described above. Preferably, a washer 209 may be provided between the metal adjusting ring 204 and the support plate 200, and the washer 209 may be made of a ceramic material to prevent contact between the support plate 200 and the metal adjusting ring 204. The washer 209 may have a notch (not denoted) to expose a lower surface of the metal adjusting ring 204 for serving as a contact portion for a conducting wire 210 embedded in the support plate 200. The lower surface of the metal adjusting ring 204 may be formed to have a structure that matches an upper end of the conducting wire 210. The conducting wire 210 is electrically connected to a DC voltage source (not shown), and thus the metal adjusting ring 204 receives a DC voltage for plasma regulation through the conducting wire 210. In one embodiment, the metal adjusting ring 204 may be applied with a 0 to 50-V DC voltage to adjust a plasma curve in the cavity.

The support plate 200 has a connector element that stabilizes the electrical connection between the conducting wire 210 and the metal adjusting ring 204. The connector element includes a wiring sleeve 211, a fixing cap 212 and a protection cover 213. The conducting wire 210 extends downwards from the support plate 200 and is enveloped by the wiring sleeve 211. The wiring sleeve 211 may be made of a ceramic material. The wiring sleeve 211 is at least partially embedded in the support plate 200, and another portion of the wiring sleeve 211 extends downwards from the support plate 200 to an exterior of the processing chamber, as shown in FIG. 5. The fixing cap 212 is configured to be fixed at the bottom of the support plate 200 and to secure the wiring sleeve 211 in the support plate 200. The fixing cap 212 may be implemented by a screw locking means. The protection cover 213 envelops the exposed wiring sleeve 211, and prevents the wiring sleeve 211 from breaking due to an inappropriate force received.

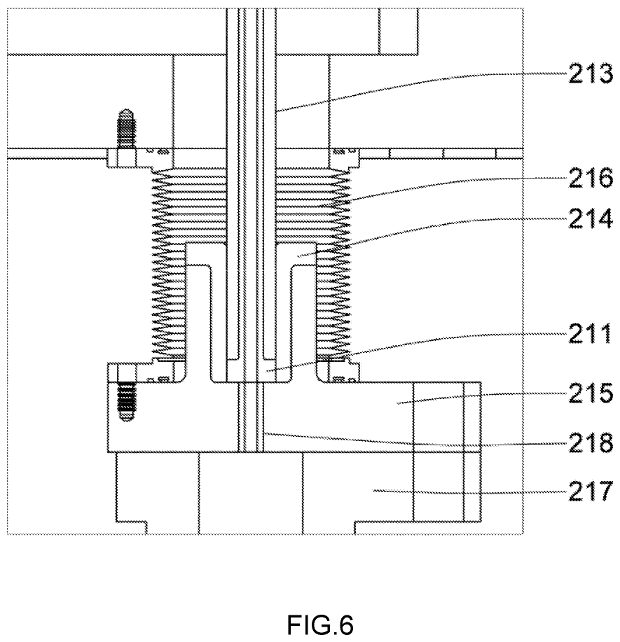

Referring to FIG. 5, in addition to ensuring the connection between the conducting wire 210 and the metal adjusting ring 204, the connector element is further used for connecting to a motion element for lifting the conducting wire 210. The motion element is configured on an outer side at the bottom of the processing chamber, and is connected to the wiring sleeve 211 below the metal adjusting ring 204. FIG. 6 shows details of the motion assembly, which includes an adaptor 214, a sealing portion 215, a corrugated tube 216 and a motion support 217. The adaptor 214 is connected to a terminal of the conducting wire 210 or the wiring sleeve 211. The adaptor 214 may be a flange adaptor. The sealing portion 215 is connected to the adaptor 214 and seals the terminals of the conducting wire 210 and the wiring sleeve 211. The sealing portion 215 and the processing chamber are connected by the corrugated tube 216 in between. The corrugated tube 216 is an elastic element to thereby achieve motions and ensure sealing at the same time. The sealing portion 215 is further connected to the motion support 217. The motion support 217 is mechanically connected to a motor (for example, the motor 101 in FIG. 1) of the support component, and is configured to be driven by the motor for lifting in synchronization. In this way, the motor for controlling the lifting of the support element is capable of synchronously driving the lifting of the motion element connected to the conducting wire 210. Thus, the conducting wire 210 and the support plate 200 can be lifted synchronously in the processing chamber. Preferably, the sealing portion 215 may further provide a sealing element 218 for sealing a partial gap existing between fitting of the conducting wire 210 and the wiring sleeve 211.

Regarding control of the device, when the support plate 200 is lifted up from a substrate transfer position (a low position) to a processing position (a high position) in the processing chamber, or vice versa, the motor also drives the motion element to lift the conducting wire 210 and the support plate 200 synchronously, thus implementing plasma processing regulated by a voltage.

The disclosure above provides comprehensive description of the manufacturing and use of combinations of the specific embodiments. Various other embodiments can be formed without departing from the spirit and scope of the disclosure above, and therefore these embodiments are encompassed within the scope of the appended claims.

What is claimed is:

1. A device for adjusting a plasma curve, comprising:
a metal adjusting ring, comprising an inner side surface, an inclined surface and a top surface, wherein the inclined surface extends downwards from the top surface to the inner side surface, the inclined surface and the top surface define an included angle, wherein the included angle is within a range of 150 degrees to 120 degrees.

2. A device for adjusting a plasma curve, comprising:
a support plate, having a carrier region and a peripheral region around the carrier region; and
a metal adjusting ring, embedded and extended in the peripheral region of the support plate, the metal adjusting ring having an inner side surface facing the carrier region, an inclined surface and a top surface, wherein the inclined surface extends downwards from the top surface to the inner side surface, the inclined surface and the top surface define an included angle, wherein the included angle is within a range of 150 degrees to 120 degrees.

3. The device for adjusting a plasma curve according to claim 2, wherein the peripheral region of the support plate has a ceramic ring, and the ceramic ring envelops the metal adjusting ring in the peripheral region of the support plate.

4. The device for adjusting a plasma curve according to claim 2, wherein at least a portion of the peripheral region of the support plate is higher than the carrier region.

5. The device for adjusting a plasma curve according to claim 2, wherein the support plate comprises a connector element, and the connector element is for electrically connecting a conducting wire to the metal regulation ring for the metal adjusting ring to receive a direct-current (DC) voltage through the conducting wire.

6. The device for adjusting a plasma curve according to claim 5, wherein the connector element comprises:
a wiring sleeve, at least partially embedded in the support plate and enveloping the conducting wire;
a fixing cap, securing the wiring sleeve in the support plate; and
a protection cover, at least partially extending to an exterior of the support plate and enveloping at least a portion of the wiring sleeve.

7. A method for controlling the device of claim 5, comprising:
lifting the support plate in a processing chamber by a motor; and
lifting the conducting wire by a motion element such that the conducting wire and the support plate elevate synchronously, wherein the motion element is mechanically connected to the motor such that the motor and the motion element move synchronously.

8. The device according to claim 7, the motion element comprises:
an adaptor, coupled to a terminal of the conducting wire;
a sealing portion, connected to the adaptor and sealing the terminal of the conducting wire;
a corrugated tube, connected to the sealing portion and enveloping the adaptor; and
a motion support, connected to the sealing portion and coupled to a motor controlling the support plate.
